(19) United States
(12) Patent Application Publication
(10) Pub. No.: US 2020/0037476 A1
(43) Pub. Date: Jan. 30, 2020

(54) COMMUNICATION MODULE AND METHOD OF MANUFACTURING THE SAME

(71) Applicant: SAMSUNG ELECTRO-MECHANICS CO., LTD., Suwon-si (KR)

(72) Inventor: Doo Hwan JUNG, Suwon-si (KR)

(73) Assignee: SAMSUNG ELECTRO-MECHANICS CO., LTD., Suwon-si (KR)

(21) Appl. No.: 16/373,210

(22) Filed: Apr. 2, 2019

(30) Foreign Application Priority Data
Jul. 24, 2018 (KR) 10-2018-0085890

(51) Int. Cl. H05K 9/00; H05K 1/18; H05K 3/34; H05K 5/03; G06K 19/06

(52) U.S. Cl. CPC H05K 9/0024; H05K 1/181; H05K 3/341; H05K 5/03; H05K 2201/10166; G06K 19/06037; H05K 2201/10371; H05K 2201/10015; H05K 9/0049

(57) ABSTRACT

A communication module includes a substrate including at least one electronic component mounted on the substrate; a shield frame coupled to the substrate and having a first recognition portion; and a shield cover covering the shield frame, and having a through-hole, which externally exposes the first recognition portion, and a second recognition portion, which is spaced apart from the through-hole.

### CROSS-REFERENCE TO RELATED APPLICATION

This application claims the benefit under 35 U.S.C. § 119(a) of Korean Patent Application No. 10-2018-0085890 filed on Jul. 24, 2018 in the Korean Intellectual Property Office, the entire disclosure of which is incorporated herein by reference for all purposes.

### BACKGROUND

### 1. Field

The following description relates to a communication module and a method of manufacturing the same.

### 2. Description of Background

Generally, a communication module product is produced through a process similar to a process of manufacturing an electrical module, and is manufactured in a production process in which a printed circuit board (PCB) assembly and a cover are assembled to each other and delivered to a customer.

When a defect occurs or reworking is required during a manufacturing process, a repair or reworking is undertaken after disassembling the cover from the PCB assembly. In this case, a label of the PCB assembly may be damaged, and it may be impossible to track the product.

Thus, it may be necessary to improve a factor which can secure traceability with only the PCB assembly when the cover is removed, and which may affect product quality by simplifying a manufacturing process.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a communication module includes a substrate including at least one electronic component mounted on the substrate; a shield frame coupled to the substrate and having a first recognition portion; and a shield cover covering the shield frame, and having a through-hole, which externally exposes the first recognition portion, and a second recognition portion, which is spaced apart from the through-hole.

The shield frame may include dividing bars forming a plurality of openings, and the dividing bars may be connected to a recognition portion forming plate on which the first recognition portion is disposed.

The through-hole may have a shape corresponding to a shape of the recognition portion forming plate.

The through-hole may have a size smaller than a size of the recognition portion forming plate.

The recognition portion forming plate may have a width greater than a width of each of the dividing bars.

The first recognition portion and the second recognition portion may be simultaneously formed.

The first recognition portion and the second recognition portion may each formed of a two-dimensional (2D) barcode.

The shield frame may include a first position determining portion disposed on one corner of the shield frame and the shield cover may include a second position determining portion disposed on one corner of the shield frame, and the first position determining portion and the second position determining portion may correspond to each other.

The shield frame may include a coupling protrusion, and the shield cover may include a coupling hole, to which the coupling protrusion may be coupled, on a side surface of the shield cover.

In another general aspect, a method of manufacturing a communication module includes mounting electronic components on a substrate; attaching a shield frame to the substrate; attaching a shield cover to the substrate; forming a first recognition portion on the shield frame; and forming a second recognition portion on the shield cover.

The method may include forming a through-hole in the shield cover for externally exposing a recognition portion forming plate of the shield frame; and forming the first recognition portion on the recognition portion forming plate.

The method may include forming the second recognition portion on an upper surface of the shield cover at a location spaced apart from the through-hole.

The method may include forming the first and second recognition portions simultaneously as two-dimensional barcodes by laser-marking.

In another general aspect, a communication module includes a substrate comprising at least one electronic component; a shield frame disposed on one surface of the substrate and comprising a plate on which a first identifier is disposed; and a shield cover to removably cover the shield frame, and including a through-hole exposing the first identifier in a configuration in which the shield cover is covering the shield frame and a second identifier disposed on the shield cover such that both the first identifier and the second identifier are visible in the configuration in which the shield cover is covering the shield frame.

The first identifier may include information on a mother lot and a son lot related to the substrate.

The shield frame may include a first position determining portion extending from a chamfered corner.

The shield cover may include a second position determining portion corresponding to the first position determining portion in the configuration in which the shield cover is covering the shield frame.

Other features and aspects will be apparent from the following detailed description, the drawings, and the claims.

### BRIEF DESCRIPTION OF DRAWINGS

FIG. 1 is a perspective diagram illustrating a communication module according to an example.

FIG. 2 is an exploded perspective diagram illustrating a communication module according to an example.

FIG. 3 is a diagram illustrating portion A illustrated in FIG. 1 in magnified form.

FIG. 4 is a flowchart illustrating a method of manufacturing a communication module according to an example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Herein, it is noted that use of the term “may” with respect to an example or embodiment, e.g., as to what an example or embodiment may include or implement, means that at least one example or embodiment exists in which such a feature is included or implemented while all examples and embodiments are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

Hereinafter, examples will be described with reference to the attached drawings.

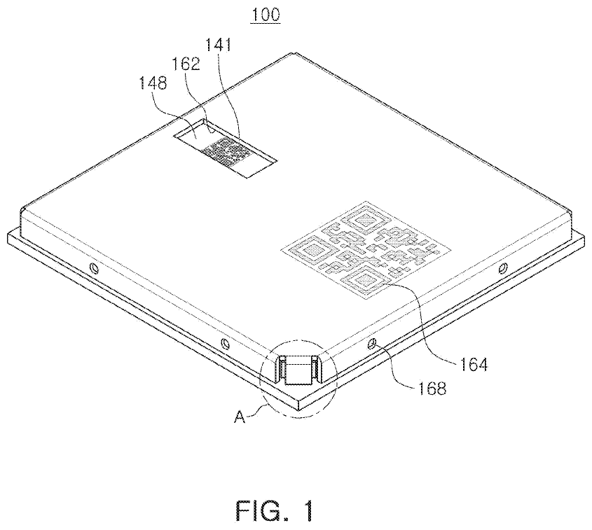

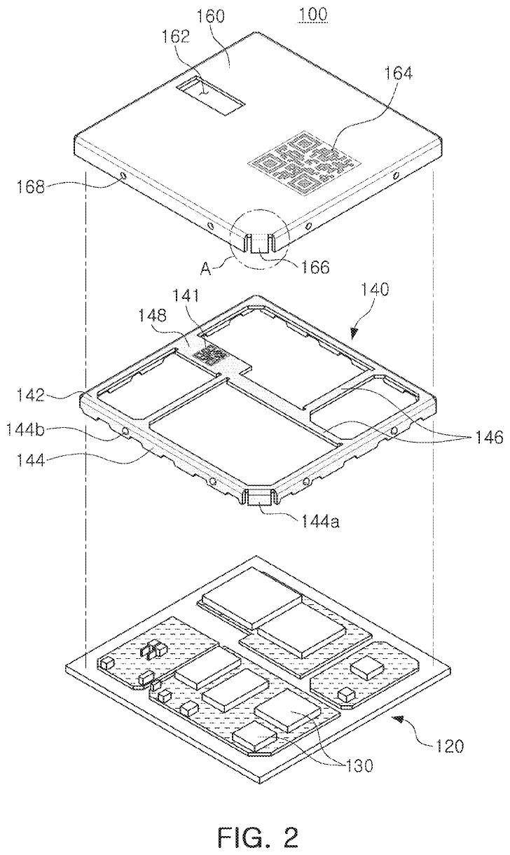

FIG. 1 is a perspective diagram illustrating a communication module according to an example. FIG. 2 is an exploded perspective diagram illustrating a communication module according to an example.

Referring to FIGS. 1 and 2, a communication module 100 may include a substrate 120, a shield frame 140, and a shield cover 160, for example.

The substrate 120 may be a wiring substrate on which a wiring pattern is formed, and a plurality of electronic components 130 mounted by a mounting method such as a soldering process, and the like, may be provided on the substrate 120. The electronic components 130 may be, for example, various types of active devices and passive devices which perform an operation of generating or processing a high frequency signal, or other operations.

As an example, the active device may include a lateral double diffused MOS (LDMOS), and the passive device may include a plurality of capacitors. The types of the active devices and passive devices may vary.

The substrate 120 may have, for example, a quadrangular plate shape, and various types of electronic components 130 may respectively be mounted on a plurality of divided regions of the substrate 120.

The shield frame 140 may be coupled to the substrate 120, and a first recognition portion 141 may be formed on the shield frame 140. As an example, the shield frame 140 may include a main frame 142, a sidewall portion 144, dividing bars 146, and a first recognition portion forming plate 148.

The main frame 142 may have, for example, an approximately quadrangular frame shape corresponding to the shape of the substrate 120. The main frame 142 may be configured such that one corner of the main frame 142 may have a shape different from shapes of the other corners. To guide a direction of assembly of the shield frame 140 with the shield cover 160, a chamfer may be formed on one of the corners of the main frame 142.

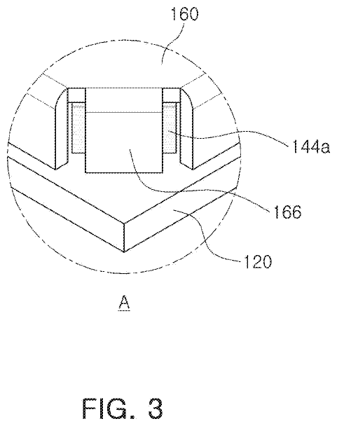

The sidewall portion 144 may extend from edges of the main frame 142 to a lower portion thereof. The sidewall portion 144 may cover side surfaces of the substrate 120. As illustrated in FIG. 3, a position determining portion 144a may be disposed on the sidewall portion 144 extending from the chamfer. Further, the sidewall portion 144 may include a coupling protrusion 144b for fixing the sidewall portion 144 to the shield cover 160.

The dividing bars 146 may divide an internal region of the main frame 142 into a plurality of openings.

One end of the recognition portion forming plate 148 may be connected to the dividing bars 146, for example, and the other end of the recognition portion forming plate 148 may be connected to the main frame 142. Also, as the first recognition portion 141 is disposed on the first recognition portion forming plate 148, the first recognition portion forming plate 148 may have a width greater than a width of the dividing bars 146.

The first recognition portion 141 may be formed of a two-dimensional (2D) barcode. Specifically, the first recognition portion 141 may be formed of a two-dimensional (2D) barcode having information (e.g., a substrate unique number) on a mother lot and a son lot. Thus, even when the shield cover 160 is removed in a final product, the information on the substrate 120 may be identified through the first recognition portion 141.

Thus, even when the shield cover 160 is removed for a repair, reworking, and the like, in a final product, traceability relating to a process may improve.

The first recognition portion 141 is not limited to a two-dimensional barcode. The first recognition portion 141 may also be a one-dimensional (1D) barcode, a quick response (QR) code, numeral strings and character strings in which information on a manufacturing date and a lot are written, or may have other types of forms.

The shield frame 140 may be formed of a metal material, such as aluminum (Al) or aluminum (Al) alloys, for example.

The shield cover 160 may cover the shield frame 140. For example, the shield cover 160 may have a box form in which a lower end portion is opened. A through-hole 162 for externally exposing the first recognition portion 141 may be formed in the shield cover 160. The through-hole 162 may have a shape corresponding to the shape of the recognition portion forming plate 148, such as a quadrangular hole shape, for example. The recognition portion forming plate 148 may have a size greater than a size of the through-hole 162.

A second recognition portion 164 spaced apart from the through-hole 162 may be disposed on an upper surface of the shield cover 160. The second recognition portion 164 may also be formed of a two-dimensional (2D) barcode, such as the first recognition portion 141. Specifically, the second recognition portion 164 may be formed of a two-dimensional (2D) barcode having information (e.g., a module unique number) on the communication module 100. The information on the communication module 100 may be identified through the second recognition portion 164. However, the second recognition portion 164 is not limited to a two-dimensional barcode. The second recognition portion 164 may also be a one-dimensional (1D) barcode, a QR code, numeral strings and character strings in which information on a manufacturing date and a lot are written, or may have other types of forms.

The first and second recognition portions 141 and 164 may be simultaneously formed during a manufacturing process. As the through-hole 162 is formed in the shield cover 160, and the recognition portion forming plate 148 is externally exposed through the through-hole 162, after the shield cover 160 is assembled into the substrate 120 and the shield frame 140, the first and second recognition portions 141 and 164 may be formed simultaneously. Also, the first and second recognition portions 141 and 164 may be formed by various methods such as a laser marking method, a printing method, and the like.

As illustrated in FIG. 3, a position determining portion 166 corresponding to the position determining portion 144a of the shield frame 140 may be formed on one of the corners of the shield cover 160. Also, a coupling hole 168 may be formed on side surfaces of the shield cover 160 such that the coupling protrusion 144b of the shield frame 140 may be coupled to the coupling hole 168.

The shield cover 160 may be formed of a metal material, such as aluminum (Al) or aluminum (Al) alloys, for example.

As described above, as the first recognition portion 141 is formed in the shield frame 140, and the second recognition portion 164 is formed on the shield cover 160, even when the shield cover 160 is removed for a repair, reworking, and the like, matters associated with a manufacturing process may be tracked.

In the description below, a method of manufacturing a communication module according to an example will be described with reference to the drawings.

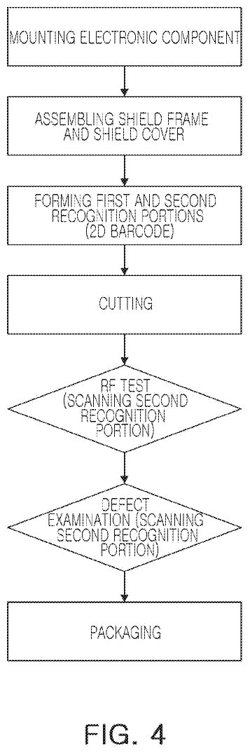

FIG. 4 is a flowchart illustrating a method of manufacturing a communication module according to an example.

Referring to FIGS. 1 to 4, a plurality of electronic components 130 may be mounted on a surface of a substrate 120. The plurality of electronic components 130 may be mounted on the substrate 120 by a mounting method such as a soldering process, and the like.

A shield frame 140 may be mounted on the substrate 120, and a shield cover 160 may be assembled to cover the shield frame 140. A recognition portion forming plate 148 of the shield frame 140 may be externally exposed through a through-hole 162 of the shield cover 160.

A first recognition portion 141 and a second recognition portion 164 may be formed on an upper surface of the recognition portion forming plate 148 and the shield cover 160, respectively. For example, the first and second recognition portions 141 and 164 may be formed by a laser marking process, a printing process, and the like. The first and second recognition portions 141 and 164 may be formed of a two-dimensional (2D) barcode, but the first and second recognition portions 141 and 164 are not limited to such a configuration. The first and second recognition portions 141 and 164 may be a one-dimensional (1D) barcode, a QR code, numeral strings and character strings in which information on a manufacturing date and a lot are written, and may have other types of forms.

In the process above, a mother lot in a manufacturing execution system (MES) may be divided into individual son lots for each substrate, and relevant unique numbers may be displayed on the first and second recognition portions 141 and 164.

A plurality of communication modules 100 may be cut into individual products.

The second recognition portion 164 formed on the shield cover 160 of the divided communication module 100 may be scanned, and an RF test may be undertaken. A result of the RF test may be stored in a server of the manufacturing execution system (MES) with reference to the unique number.

After scanning the second recognition portion 164 formed on the shield cover 160 of the divided communication module 100, a defect examination process may be performed. A result of the defect examination process may also be stored in the server of the manufacturing execution system (MES) with reference to the unique number.

As described above, as the first recognition portion 141 is formed in the shield frame 140, and the second recognition portion 164 is formed on the shield cover 160, even when the shield cover 160 is removed for a repair, reworking, and the like, matters associated with a manufacturing process may be tracked.

Therefore, according to the examples, even when a final product is dissembled for a repair, reworking, and the like, traceability may be secured.

The examples provide a communication module which can secure traceability even when a final product is disassembled for a repair, reworking, or for other purposes, and a method of manufacturing the same.

The method illustrated in FIG. 4 that performs the operations described in this application are performed by computing hardware, for example, by one or more processors or computers, implemented as described above executing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions in the specification, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access memory (RAM), flash memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A communication module, comprising:
a substrate comprising at least one electronic component mounted on the substrate;
a shield frame configured to be coupled to the substrate and comprising a first recognition portion; and
a shield cover configured to cover the shield frame, and comprising a through-hole, which is configured to externally expose the first recognition portion, and a second recognition portion, which is spaced apart from the through-hole.

2. The communication module of claim 1, wherein the shield frame comprises dividing bars forming a plurality of openings, and the dividing bars are connected to a recognition portion forming plate on which the first recognition portion is disposed.

3. The communication module of claim 2, wherein the through-hole has a shape corresponding to a shape of the recognition portion forming plate.

4. The communication module of claim 2, wherein the through-hole has a size smaller than a size of the recognition portion forming plate.

5. The communication module of claim 2, wherein the recognition portion forming plate has a width greater than a width of each of the dividing bars.

6. The communication module of claim 1, wherein the first recognition portion and the second recognition portion are simultaneously formed.

7. The communication module of claim 1, wherein the first recognition portion and the second recognition portion are each formed of a two-dimensional (2D) barcode.

8. The communication module of claim 1, wherein the shield frame comprises a first position determining portion disposed on one corner of the shield frame and the shield cover comprises a second position determining portion disposed on one corner of the shield frame, and the first position determining portion and the second position determining portion correspond to each other.

9. The communication module of claim 1, wherein the shield frame comprises a coupling protrusion, and the shield cover comprises a coupling hole, to which the coupling protrusion is coupled, on a side surface of the shield cover.

10. A method of manufacturing a communication module, comprising:
mounting electronic components on a substrate;
attaching a shield frame to the substrate;
attaching a shield cover to the substrate;
forming a first recognition portion on the shield frame; and
forming a second recognition portion on the shield cover.

11. The method of claim 10, further comprising:
forming a through-hole in the shield cover for externally exposing a recognition portion forming plate of the shield frame; and
forming the first recognition portion on the recognition portion forming plate.

12. The method of claim 11, further comprising forming the second recognition portion on an upper surface of the shield cover at a location spaced apart from the through-hole.

13. The method of claim 10, further comprising forming the first and second recognition portions simultaneously as two-dimensional barcodes by laser-marking.

14. A communication module, comprising:
a substrate comprising at least one electronic component;
a shield frame disposed on one surface of the substrate and comprising a plate on which a first identifier is disposed; and
a shield cover configured to removably cover the shield frame, and comprising a through-hole exposing the first identifier in a configuration in which the shield cover is covering the shield frame and a second identifier disposed on the shield cover such that both the first identifier and the second identifier are visible in the configuration in which the shield cover is covering the shield frame.

15. The communication module of claim 14, wherein the first identifier comprises information on a mother lot and a son lot related to the substrate.

16. The communication module of claim 14, wherein the shield frame comprises a first position determining portion extending from a chamfered corner.

17. The communication module of claim 16, wherein the shield cover comprises a second position determining portion corresponding to the first position determining portion in the configuration in which the shield cover is covering the shield frame.
